(19) United States
(12) Patent Application Publication
(10) Pub. No.: US 2023/0209768 A1
(43) Pub. Date: Jun. 29, 2023

(54) STRUCTURE OF UNIFORM-TEMPERATURE HEAT DISSIPATION DEVICE

(71) Applicant: TEAM GROUP INC., NEW TAIPEI CITY (TW)

(72) Inventors: CHIN FENG CHANG, NEW TAIPEI CITY (TW); KUAN TING CHEN, NEW TAIPEI CITY (TW)

(21) Appl. No.: 17/572,951

(22) Filed: Jan. 11, 2022

(30) Foreign Application Priority Data
Dec. 28, 2021 (TW) 110149067

(51) Int. Cl. H05K 7/20; F28D 21/00

(52) U.S. Cl. CPC H05K 7/20263; H05K 7/20409; F28D 21/00; F28D 2021/0029

(57) ABSTRACT

The present invention provides a structure of uniform-temperature heat dissipation device. A thermal plate is disposed on a heat-emitting device on a substrate correspondingly. A thermal assembly is disposed on the thermal plate correspondingly and includes an outer casing and a thermal casing. The outer casing is disposed on the thermal plate. The thermal casing is disposed inside the outer casing. The thermal casing includes a heat dissipation fluid inside. By using the flow of the heat dissipation fluid inside the thermal casing, the heat from the heat-emitting device can be dissipated rapidly. Finally, a first heat dissipation member and a limiting recess clamp the outer casing and the first heat dissipation member can further dissipate the heat from the thermal assembly.

### FIELD OF THE INVENTION

The present invention relates generally to a structure of uniform-temperature heat dissipation device, and particularly a heat dissipation device using internal fluid for heat dissipation.

### BACKGROUND OF THE INVENTION

As technologies are developed, modern computer hardware is evolved toward the high-speed and high-frequency trend for increasing its operational efficiency. Under long-term operations in high-speed and high-frequency environments, computer hardware tends generate massive heat. To match the high-speed operations of processors, the operating temperature of memories become higher increasingly. The continuous increase in temperature definitely will affect the performance of memories or even damage them.

Due to the prosperity of e-sports and the trend of computer modification, many e-sports participants will replace the e-sports computer casings by transparent ones. The internal components of e-sports computers, such as CPUs, display cards, and memories, own superior performance to those in normal personal computers and hence generating more heat. Unfortunately, excess heat will degrade the performance of electronic devices. Thereby, people will install heatsinks to these electronic devices. In the e-sports industry, the heatsinks installed on electronic devices need not only outstanding heat dissipation efficiency but also exceptional appearance designs.

As the time evolves, the equipment for the industrial Internet of things (Hop in industrial production or traffic utilities is developed gradually. While applying IoT to terminal devices in special environments, intelligent edge computing, and 5G communication, the data transmission in solid-state disks and memories is required to be low-power and small so that the equipment can perform uninterrupted high-speed data processing and operations in limited space. Consequently, the substantial heat generated imposes a great challenge to the performance and stability of the data transmission in industrial solid-state disks and memories.

The electronic elements that emit heat according to the prior art comprises circuit boards and a plurality of heat-emitting devices, such as nonvolatile memories, disposed on the surfaces thereof and are connected to computer systems via connection interfaces. Due to the demand in e-sports products as described above, the operating frequencies of related electronic devices tend to move to higher frequencies. Although the electronic devices gain higher data transmission rates, they consume more power, which leads to tendency of heat accumulation. As the operating temperatures of electronic devices become higher or even exceeding the tolerable temperature limits, their performance will degrade apparently. In addition, the data retention of modules or the error rates of operations will increase, leading o instability of computer systems.

Owing to consumers' requirements, the heat dissipation in electronic devices should be rapid and uniform. Thereby, many casings or plates that can accelerate heat dissipation are designed and attached to memories by thennal paste for improving the heat dissipation efficiency of electronic devices.

To solve the above problems in the prior art, the present invention provides a structure of uniform-temperature heat dissipation device. A thermal plate is disposed on a heat-emitting device on a substrate correspondingly. A thermal assembly is disposed on the thermal plate correspondingly and includes an outer casing and a thermal casing. The thermal casing includes a heat dissipation fluid. A first heat dissipation member is further used to dissipate the heat in the thermal assembly. By using the thermal plate, the thermal assembly, and the first heat dissipation member, the heat-emitting device can be cooled down rapidly.

### SUMMARY

An objective of the present invention is to provide a structure of uniform-temperature heat dissipation device. A thermal plate is disposed on a heat-emitting device on a substrate correspondingly. A thermal assembly is disposed on the thermal plate correspondingly and includes an outer casing. The outer casing include a thermal casing. The thermal casing includes a heat dissipation fluid. By using the flow of the heat dissipation fluid inside the thermal casing, the heat from the heat-emitting device can be transferred to the thermal assembly. A first heat dissipation member is further used to dissipate the heat in the thermal assembly. Thereby, the heat from the heat-emitting device can be dissipated uniformly and rapidly and thus providing a heat dissipation device that can dissipate heat uniformly.

To achieve the above objective of effect, the present invention provides a structure of uniform-temperature heat dissipation device, which comprises a substrate, a thermal plate, a thermal assembly, and a first heat dissipation member. A heat-emitting device is disposed on the substrate. The thermal plate is disposed on a heat-emitting device on the substrate correspondingly. The thermal assembly includes an outer casing and a thermal casing. The outer casing is disposed on the thermal plate. The thermal casing is disposed inside the outer casing. A heat dissipation fluid is disposed inside the thermal casing. The thermal casing includes a plurality of pillars penetrating the thermal casing. The heat dissipation fluid is disposed in the thermal casing and located among the plurality of pillars. A limiting recess is disposed below the first heat dissipation member. The inner side of the limiting recess clamps the outer casing. By using the structure, a heat dissipation device that can uniformly dissipate heat is provided.

According to an embodiment of the present invention, the thennal plate is silica gel.

According to an embodiment of the present invention, the plurality of pillars are copper tubes.

According to an embodiment of the present invention, the structure further comprises thermal paste disposed between the outer casing of the thermal assembly and the first heat dissipation member and inside the limiting recess.

According to an embodiment of the present invention, the heat dissipation fluid is water.

According to an embodiment of the present invention, a fin heatsink is disposed on the first heat dissipation member.

According to an embodiment of the present invention, the structure further comprises a first thermal glue member disposed between the outer casing of the thermal assembly and the first heat dissipation member.

According to an embodiment of the present invention, the structure further comprises a second heat dissipation member disposed below the substrate.

According to an embodiment of the present invention, the structure further comprises a second thermal glue member disposed between the substrate and the second heat dissipation member.

### BRIEF DESCRIPTION OF THE DRAWINGS

FIG. 1 shows an exploded view of the structure according to an embodiment of the present invention;

FIG. 2 shows a schematic view of the thermal assembly according to an embodiment of the present invention;

FIG. 3 shows a schematic view of the structure of the thermal assembly according to an embodiment of the present invention;

FIG. 4 shows a schematic diagram of other components according to an embodiment of the present invention;

FIG. 5 shows an exploded view of the structure according to another embodiment of the present invention; and

FIG. 6 shows a schematic view of the thennal assembly according to another embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

To solve the above problem according to the prior art, the structure according to the present invention comprises a thermal plate disposed on a substrate including a heat-emitting device, a thermal assembly, and a first heat dissipation member disposed on the heat-emitting device correspondingly for dissipating heat uniformly. The thermal assembly includes a thermal casing disposed inside an outer casing. A heat dissipation fluid is disposed inside the thermal casing. The thermal assembly is then disposed to a limiting recess of the first heat dissipation member. By using the flow of the heat dissipation fluid inside the thermal casing, the heat from the heat-emitting device can be further dissipated uniformly and rapidly.

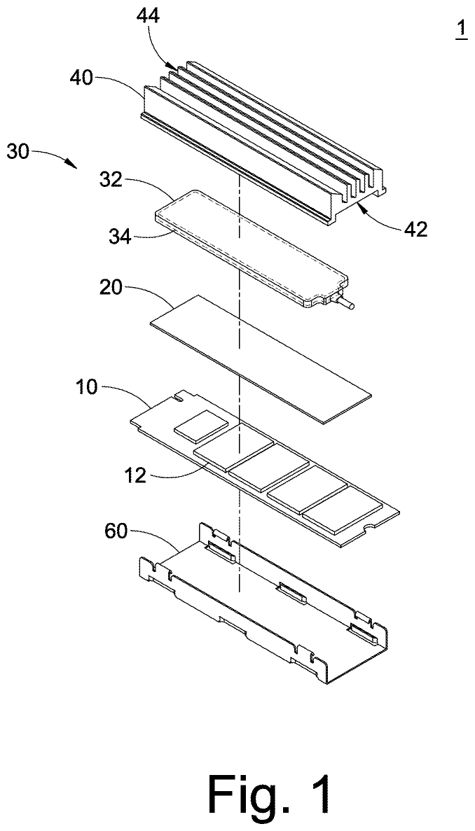

Please refer to FIG. 1, which shows an exploded view of the structure according to an embodiment of the present invention. As shown in the figure, according to the present embodiment, a structure of uniform-temperature heat dissipation device 1 comprises a substrate 10, a thermal plate 20, a thermal assembly 30, and a first heat dissipation member 40. According to the present embodiment, the substrate 10 is a circuit board, for example, a circuit board for memories. Nonetheless, the present embodiment is not limited to the example.

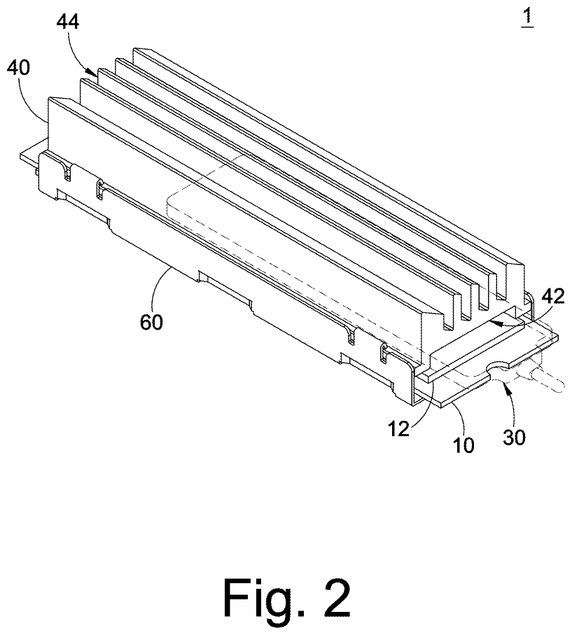

Please refer again to FIG. 1 and to FIG. 2, which shows a schematic view of the thermal assembly according to an embodiment of the present invention. As shown in the figures, according to the present embodiment, a heat-emitting device 12, such as a chip, is disposed on the substrate 10. The thermal plate 20 is disposed on the heat-emitting device 12 corresponding to the location of the heat-emitting device 12. In addition, the thermal plate 20 envelops an outer edge of the heat-emitting device 12 so that the thermal plate 20 can contact the heat-emitting device 12 firmly. According to the embodiment with a plurality of heat-emitting devices 12, the thermal plate 20 can fill the gaps between individual heat-emitting devices correspondingly. The thermal assembly 30 includes an outer casing 32 and a thermal casing 34. The outer casing 32 is disposed on the thermal plate 20 corresponding to the location of the thermal plate 20 to contact the thermal plater 20. A heat dissipation fluid A (not shown in the figure) is disposed inside the thermal casing 34. A limiting recess 42 is disposed below the first heat dissipation member 40. An inner side of the limiting recess 42 clamps the outer casing 32 for fixing the outer casing 32 to the inner side of the limiting recess 42. The thermal assembly 30 and the first heat dissipation member 40 are mutually wedged for avoiding movement of the thermal assembly 30 and the first heat dissipation member 40.

According to the present embodiment, the thermal plate 20 is silica gel. Furthermore, it is thermal pad, which is a solid-state material and a thermal interface material. Generally, thermal pads are formed in a plate shape for application. The main function is to fill the micro voids at the junction or contact between two materials or the uneven holes on surfaces for further reducing the impedance for heat transfer.

According to the present embodiment, a fin heatsink 44 is further disposed on the first heat dissipation member 40 for increasing the surface area to contact the air and thus enhancing the heat dissipation efficiency of the first heat dissipation member 40. The fin heatsink 44 can be, but not limited to, plate-, pillar-, or ring-shaped.

According to the present embodiment, the structure further comprises a second heat dissipation member 60 disposed below the substrate 10. The second heat dissipation member 60 and the first heat dissipation member 40 are mutually wedged for clamping the substrate 10, the thermal plate 20, and the thermal assembly 30. The second heat dissipation member 60 and the first heat dissipation member 40 are used to protect the internal devices and avoid device wearing.

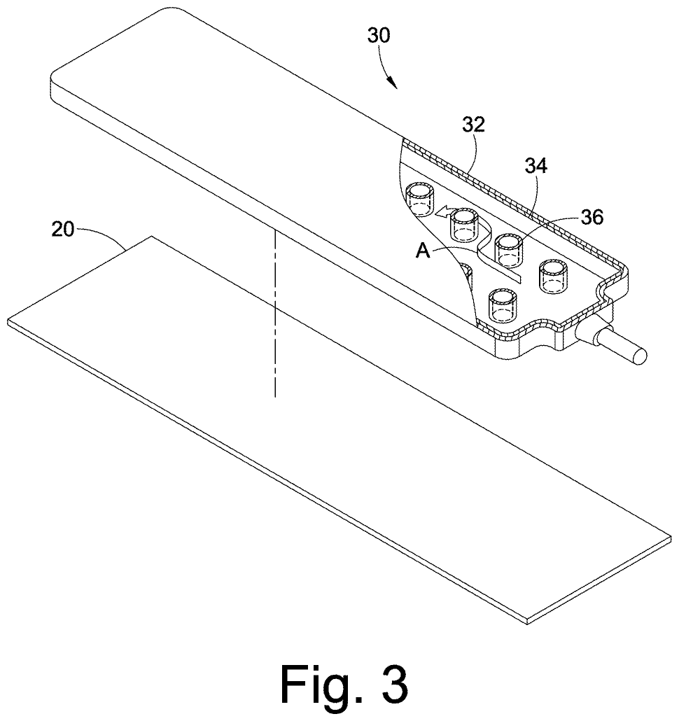

Please refer to FIG. 3, which shows a schematic view of the structure of the thermal assembly according to an embodiment of the present invention. As shown in the figure, according to the present embodiment, the thermal casing 34 of the thermal assembly 30 includes a plurality of pillars 36 penetrating both the top and bottom sides of the thermal casing 34. The heat dissipating fluid A is disposed inside the thermal casing 34 and located between the plurality of pillars 36. According to the present embodiment, the outer casing 32 absorbs the heat from the thermal plate 20 and transfers a portion of the heat to the thermal casing 34. The plurality of pillars 36 are used to increase the surface area to contact the heat dissipation fluid A. When the thermal casing 34 absorbs the heat transferred by the outer casing 32, the heat dissipation fluid A flows among the plurality of pillars 36 for transferring the heat to the whole thermal casing 34 uniformly.

According to the present embodiment, the plurality of pillars 36 are copper tubes used for dissipating the heat from the thermal casing 34 rapidly. The heat dissipation fluid A is water. After the thermal casing 34 is filled with the heat dissipation fluid A, the opening is sealed using a metal member. Nonetheless, the present embodiment is not limited to the example.

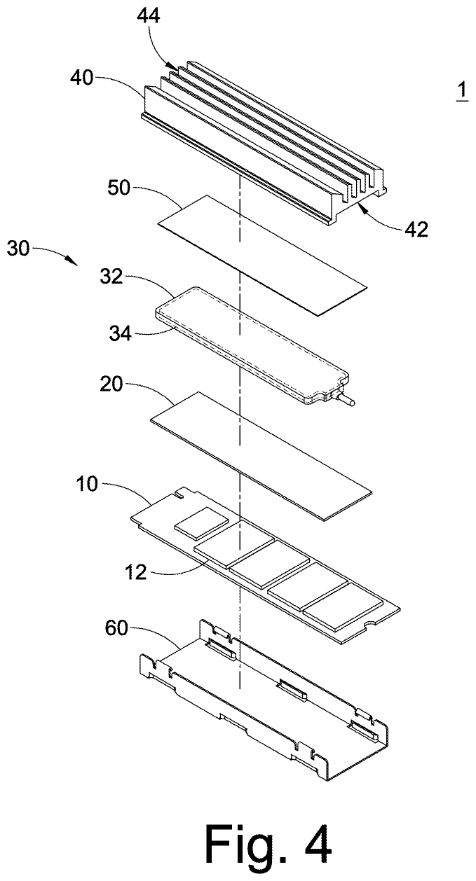

Please refer to FIG. 4, which shows a schematic diagram of other components according to an embodiment of the present invention. As shown in the figure, according to the present embodiment, the structure further comprises thermal paste 50 disposed between the outer casing 32 of the thermal assembly 30 and the first heat dissipation member 40 and located inside the limiting recess 42. The thermal paste 50 is used for filling the gaps between the outer casing 32 of the thermal assembly 30 and the limiting recess 42 for increasing, the efficiency of heat transfer. According to the present embodiment, the thermal paste 50 includes liquid base materials containing polymers and stuffing materials. The example of the base materials include silicone, polyurethane, acrylate polymers, hot glue, or pressure sensitive adhesives. The examples of stuffing materials include aluminum oxide, boron nitride, or zinc oxide.

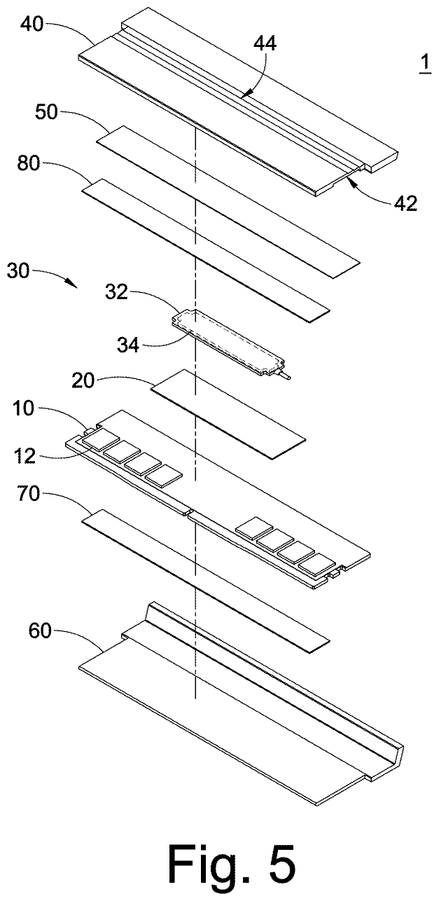

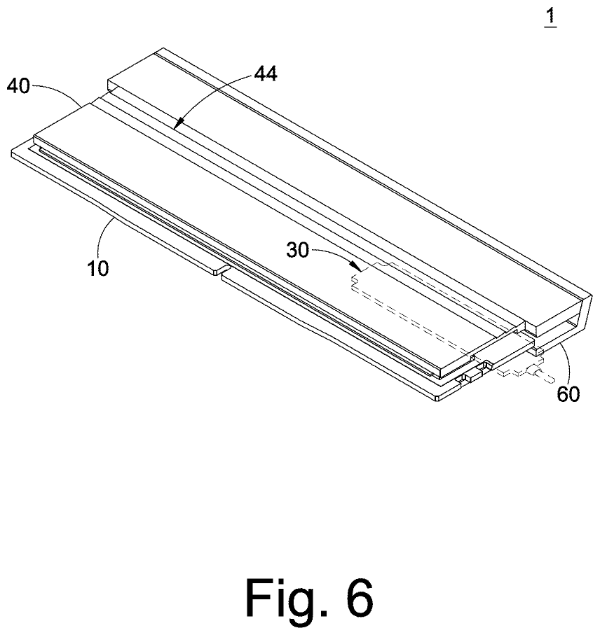

Please refer to FIG. 5 and FIG. 6. FIG. 5 shows an exploded view of the structure according to another embodiment of the present invention; FIG. 6 shows a schematic view of the thermal assembly according to another embodiment of the present invention. As shown in the figures, a structure of uniform-temperature heat dissipation device 1 according to another embodiment is disclosed. The structure comprises the substrate 10, the thermal plate 20, the thermal assembly 30, the first heat dissipation member 40, and the second heat dissipation member 60. Their connection is the same as the one illustrated in the previous embodiment. Hence, the details will not be described again.

The structure according to the present embodiment further comprises a first thermal glue member 70 and a second thermal glue member 80. The first thermal glue member 70 is disposed between the outer casing 32 of the thermal assembly 30 and the first heat dissipation member 40. The second thermal glue member 80 is disposed between the substrate 10 and the second heat dissipation member 60. The first thermal glue member 70 and the second thermal glue member 80 can further fix the substrate 10, the thermal plate 20, and the thermal assembly 30 between the first heat dissipation member 40 and the second heat dissipation member 60 for enhancing the efficiency of heat transfer using thermal materials.

According to the present embodiment, the first thermal glue member 70 and the second thermal glue member 80 are thermal double-sided tapes (heat-dissipation double-sided tapes), which are formed by mixing polymers with thermal ceramic powders and adhesives and coating on both sides of glass fibers. They are highly thermally conductive and electrically insulative with certain flexibility.

To sum up, the present invention provides a structure of uniform-temperature heat dissipation device. A thermal plate is disposed on a heat-emitting device on a substrate correspondingly. A thermal assembly is disposed on the theiinal plate correspondingly and includes an outer casing and a thermal casing. The outer casing is disposed on the thermal plate. The thermal casing is disposed inside the outer casing. The thermal casing includes a heat dissipation fluid inside. By using the flow of the heat dissipation fluid inside the thermal casing, the heat from the heat-emitting device can be dissipated rapidly. Finally, a first heat dissipation member and a limiting recess clamp the outer casing and the first heat dissipation member can further dissipate the heat from the thermal assembly. As the operating temperatures of electronic devices become higher or even exceeding the tolerable temperature limits, their perfoiiiiance will degrade apparently. In addition, the data retention of modules or the error rates of operations will increase, leading o instability of computer systems. Hence, the present invention solves these problems encountered in the prior art.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

What is claimed is:

1. A structure of uniform-temperature heat dissipation device, comprising:
a substrate, including a heat-emitting device thereon;
a thermal plate, disposed on said heat-emitting device correspondingly, and enveloping an outer edge of said heat-emitting device;
a thermal assembly, including an outer casing and a thermal casing, said outer casing disposed on said thermal plate and enveloping said thermal casing,
a heat dissipation fluid disposed inside said thermal casing, said thermal casing including a plurality of pillars, said plurality of pillars penetrating said thermal casing, respectively, and said heat dissipation fluid disposed in said thermal casing and located among said plurality of pillars; and
a first heat dissipation member, including a limiting recess therebelow, and an inner side of said limiting recess clamping said outer casing.

2. The structure of uniform-temperature heat dissipation device of claim 1, wherein said thermal plate is silica gel.

3. The structure of uniform-temperature heat dissipation device of claim 1, wherein said plurality of pillars are copper tubes.

4. The structure of uniform-temperature heat dissipation device of claim 1, and further comprising thermal paste, disposed between said outer casing of said thermal assembly and said first heat dissipation member and inside said limiting recess.

5. The structure of uniform-temperature heat dissipation device of claim 1, wherein said heat dissipation fluid is water.

6. The structure of uniform-temperature heat dissipation device of claim 1, wherein a fin heatsink is disposed on said first heat dissipation member.

7. The structure of uniform-temperature heat dissipation device of claim 1, and further comprising a first thermal glue member, disposed between said outer casing of said thermal assembly and said first heat dissipation member.

8. The structure of uniform-temperature heat dissipation device of claim 1, and further comprising a second heat dissipation member, disposed below said substrate.

9. The structure of uniform-temperature heat dissipation device of claim 8, and further comprising a second thermal glue member, disposed between said substrate and said second heat dissipation member.
